(19) United States
(12) Patent Application Publication
(10) Pub. No.: US 2015/0022285 A1
(43) Pub. Date: Jan. 22, 2015

(54) BANDPASS FILTER

(71) Applicant: CyberTAN Technology, Inc., Hsinchu (TW)

(72) Inventor: CHIA-HO HUNG, Hsinchu (TW)

(21) Appl. No.: 14/330,477

(22) Filed: Jul. 14, 2014

(30) Foreign Application Priority Data
Jul. 19, 2013 (TW) 102126024

(51) Int. Cl. H01P 1/203

(52) U.S. Cl. CPC H03H 7/12
USPC 333/204

(57) ABSTRACT

A bandpass filter includes a first uniform impedance resonator comprising a first microstrip line and a second microstrip line, a second uniform impedance resonator which is axisymmetric to the first uniform impedance resonators, a first asymmetric stepped-impedance resonator comprising a third microstrip line and a fourth microstrip line, a second asymmetric stepped-impedance resonator which is axisymmetric to the first asymmetric stepped-impedance resonator, a third asymmetric stepped-impedance resonator consisting of a fifth microstrip line and a sixth microstrip line, a fourth asymmetric stepped-impedance resonator which is axisymmetric to the third asymmetric stepped-impedance resonator, a input consisting of a seventh microstrip line and connecting with the first microstrip line, and a output which is axisymmetric to the input and connects with the second uniform impedance resonator.

### FIELD

Embodiments of the present disclosure generally relate to high frequency component, and more particularly to a bandpass filter.

### BACKGROUND

A filter is a necessary high frequency component in some mobile devices, its function is to choose proper frequencies, namely, the filter passes some signals with proper frequencies and prevents some signals with improper frequencies. Filters with a narrow bandwidth tend to have bad frequency selectivity, which cannot meet multi-frequency service needs of many devices.

### BRIEF DESCRIPTION OF THE DRAWINGS

FIG. 1 is an embodiment of a bandpass filter.

FIG. 2 is another embodiment of a bandpass filter.

FIG. 3 is a unrolled diagram of a first asymmetric stepped-impedance resonator.

FIG. 4 is a unrolled diagram of a third asymmetric stepped-impedance resonator.

FIG. 5 is a relation diagram between resonate frequencies and sizes of a asymmetric stepped-impedance resonator.

FIG. 6 is frequency diagram of the bandpass filter of FIG. 1.

### DETAILED DESCRIPTION

The following illustrative embodiments are provided to illustrate the disclosure of the present disclosure, these and other advantages and effects can be apparent to those skilled in the art after reading the disclosure of this specification.

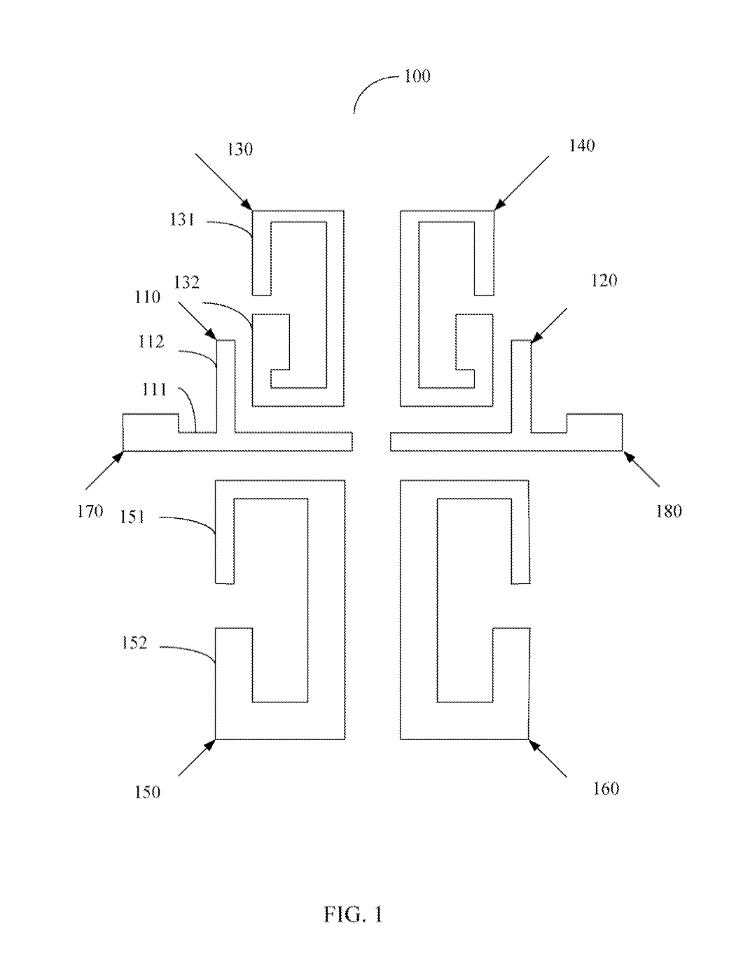

FIG. 1 is an embodiment of a bandpass filter 100. In the embodiment, a size of the bandpass filter is 20.8 mm by 24.2 mm, and the bandpass filter 100 is designed on a substrate which is RT/Duroid 5880, parameters of the substrate are dielectric constant (2.2), loss tangent (0.0009) and thickness (0.787 mm). However, the size and the parameters of the present disclosure should not be limited by the above-described embodiments.

In the embodiment of FIG. 1, the bandpass filter 100 includes a first uniform impedance resonators 110, a second uniform impedance resonator 120, a first asymmetric stepped-impedance resonator 130, a second asymmetric stepped-impedance resonator 140, a third asymmetric stepped-impedance resonator 150, a fourth asymmetric stepped-impedance resonator 160, an input 170 and an output 180.

In the present embodiment of FIG. 1, the first uniform impedance resonator 110 and the second uniform impedance resonator 120 are axisymmetric to each other. The first asymmetric stepped-impedance resonator 130 and the second asymmetric stepped-impedance resonator 140 are axisymmetric to each other. The third asymmetric stepped-impedance resonator 150 and the fourth asymmetric stepped-impedance resonator 160 are axisymmetric to each other. All resonators are on the same plane.

In the present embodiment of FIG. 1, the first uniform impedance resonator 110 consists of a first microstrip line 111 and a second microstrip line 112, the first microstrip line 111 is perpendicular to the second microstrip line 112 so that a “T” shape is presented. Besides, width of the first microstrip line 111 and width of the second microstrip line 112 are same.

In the present embodiment of FIG. 1, the first asymmetric stepped-impedance resonator 130 consists of a third microstrip line 131 and a fourth microstrip line 132 and is located on one side of the first microstrip line 111. In the embodiment, the third microstrip line 131 connects with the fourth microstrip line 132 to collectively form a first rectangle defining a first gap, on the side perpendicular to the first microstrip line 111 without making connection. The first gap is located between the third microstrip line 131 and the fourth microstrip line 132. In the embodiment, width of the fourth microstrip line 132 is wider than width of the third microstrip line 131, and the fourth microstrip line 132 is located on the side defining the first gap and is close to the first microstrip line 111.

In the present embodiment of FIG. 1, the third asymmetric stepped-impedance resonator 150 consists of a fifth microstrip line 151 and a sixth microstrip line 152 and is located on one other side of the first microstrip line 111. In the embodiment, the fifth microstrip line 151 connects with the sixth microstrip line 152 to collectively form a second rectangle defining a second gap, one side defining the second gap is perpendicular without connection to the first microstrip line 111.

In the present embodiment of FIG. 1, viewing the second rectangle clockwise from the second gap, the second rectangle has a first straight line, a second straight line, a third straight line, a fourth straight line and a fifth straight line. The first straight line and the fifth straight line are located on one side defining the second gap, and the gap is located between the fifth straight line and the fourth straight line. In addition, the first straight line and the fifth straight line are consist of the fifth microstrip line 151, the third straight line, the fourth straight line and the fifth straight line are consist of the sixth microstrip line 152. Width of the fifth microstrip line 151 is wider than width of the sixth microstrip line 152.

The input portion 170 and the output portion 180 are axisymmetric to each other, and the input portion 170 connects with one end of the first microstrip line 111. In the embodiment, the second microstrip line 112 and the first asymmetric stepped-impedance resonator 130 are located on one side of the first microstrip line 111, and the microstrip line 112 is close to the input portion 170.

In the present embodiment of FIG. 1, the first uniform impedance resonators 110 and the second uniform impedance resonator 120 are used to couple the first asymmetric stepped-impedance resonator 130, the second asymmetric stepped-impedance resonator 140, the third asymmetric stepped-impedance resonator 150 and the fourth asymmetric stepped-impedance resonator 160. The shape of the first uniform impedance resonators 110 and the shape of the second uniform impedance resonator 120 are designed based on their best coupling distance. In addition, the shapes of the first asymmetric stepped-impedance resonator 130, the second asymmetric stepped-impedance resonator 140, the third asymmetric stepped-impedance resonator 150 and the fourth asymmetric stepped-impedance resonator 160 be designed to get a best resonance frequency.

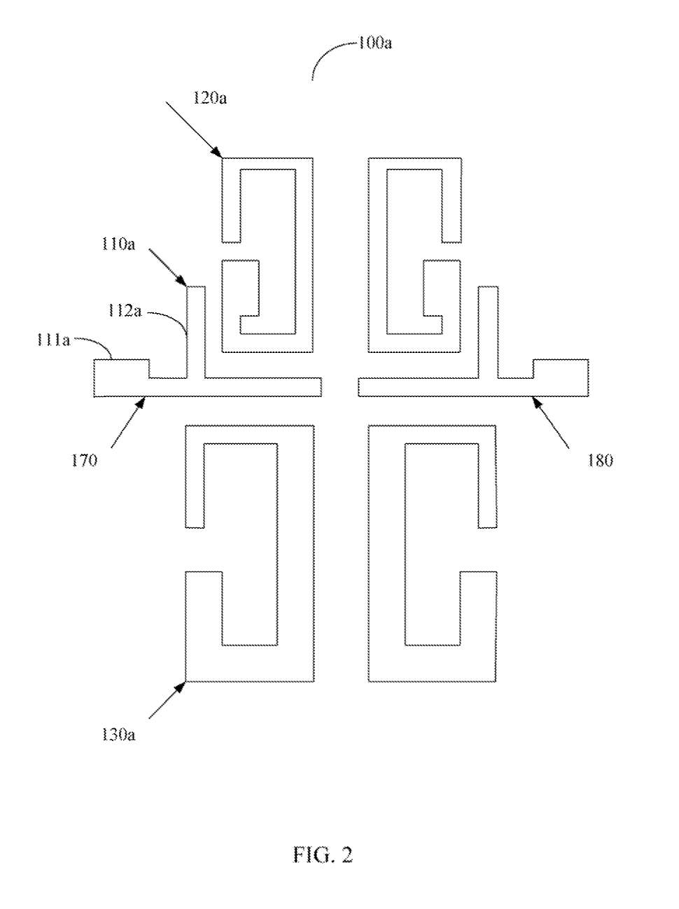

FIG. 2 shows another embodiment of a bandpass filter 100a. In the present embodiment, the bandpass filter 110a has two sets of resonators, and each resonator has a first filter 110a, a second resonator 120a and a third resonator 130a.

In the present embodiment of FIG. 2, the first resonator 110a has a seventh microstrip line 111a which presents a “L” shape and a eighth microstrip line 112a which is elongated. In the embodiment, the seventh microstrip line 111a has a long part and a short part which are perpendicular to each other, and the short part is wider than the long part. In addition, the eighth microstrip lines 112a are attached perpendicular to the long part.

In the present embodiment of FIG. 2, the second resonator 120a presents a third rectangle defining a third gap, and is located on one opposite side of the eighth microstrip line 112a corresponding to the short part of the seventh microstrip line 111a. In the embodiment, one part of the second resonator 120a near the third gap and the eighth microstrip line 112a is wider than other parts of the second resonator 120a.

In the present embodiment of FIG. 2, the third resonator 130a presents a fourth rectangle defining a fourth gap, and is located on an opposite side of the long part of the seventh microstrip line 111a corresponding to the second resonator 130a. In the embodiment, viewing the rectangle clockwise from the fourth gap, the rectangle has a first straight line, a second straight line, a third straight line, a fourth straight line and a fifth straight line, and widths of the first straight line and the second straight line are wider than widths of the third straight line, the fourth straight line and the fifth straight line.

In addition, in the above two sets of resonators, the joint of the long part and the short part in the seventh microstrip line 111a is set as the input portion 170 or the output portion 180.

The above two embodiments are two different descriptions about the bandpass filter 100, but the bandpass filters 100 or the bandpass filter 100a which are referred to in the two descriptions have the same shape and functions.

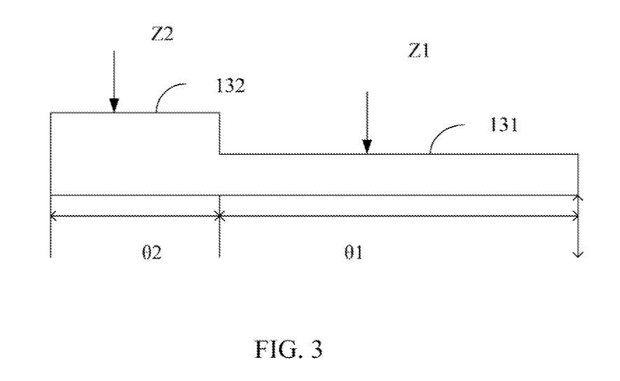

FIG. 3 is a unrolled diagram of the first asymmetric stepped-impedance resonator 130, a shape showed in FIG. 3 can be achieved by stretching the first asymmetric stepped-impedance resonator 130. In FIG. 3, a narrow part equated to the third microstrip line 131 in FIG. 1 and is also represented by 131, a wider part equated to the fourth microstrip line 132 and is also represented by 132.

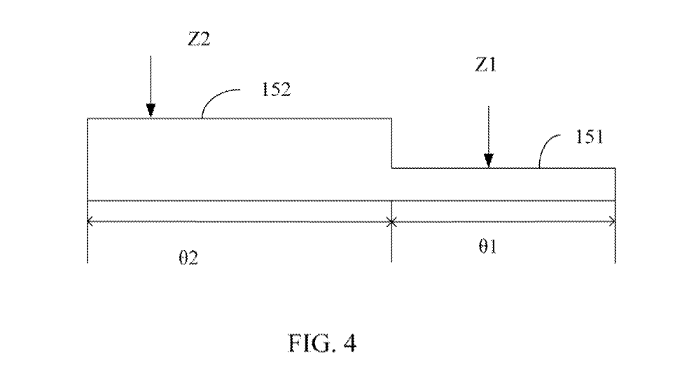

FIG. 4 is a unrolled diagram of the third asymmetric stepped-impedance resonator 140, a shape showed in FIG. 4 can be achieved by stretching the third asymmetric stepped-impedance resonator 150. In FIG. 4, a narrow part equated to the fifth microstrip line 151 in FIG. 1 and is also represented by 151, a wider part equated to the sixth microstrip line 152 and is also represented by 152.

FIG. 3 and FIG. 4 consist of a high impedance part and a low impedance part, and in FIG. 3 and in FIG. 4, Z1 presents the impedance value of the high impedance part, Z2 presents the impedance value of the low impedance part, θ1 presents the length of the high impedance part, θ2 presents the length of the low impedance part. That is, Z1 presents the impedance value of the third microstrip line 131 and the fifth microstrip line 151, Z2 presents the impedance value of the fourth microstrip line 132 and the sixth microstrip line 152, θ1 presents the length of the third microstrip line 131 and the fifth microstrip line 151, θ2 presents the length of the fourth microstrip line 132 and the sixth microstrip line 152. In the present embodiment, a impedance ratio K=Z2/Z1, and the electronic length ratio α=θ2/(θ1+θ2).

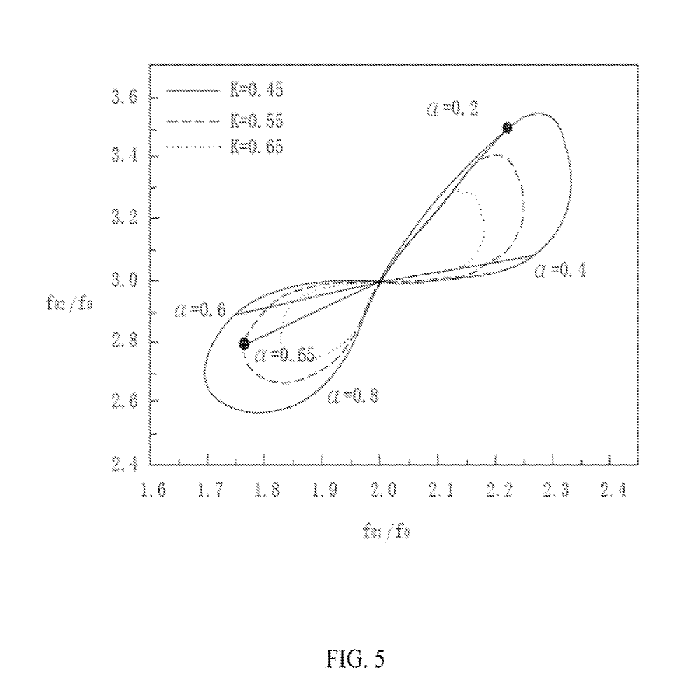

FIG. 5 is a relation diagram between resonate frequencies and sizes of the asymmetric stepped-impedance resonator. In FIG. 5, K is the impedance ratio, α is electronic length ratio, abscissa (fs1/f0) presents a ratio between a first frequency multiplication and a central frequency, ordinate (fs2/f0) presents a ratio between a second frequency multiplication and the central frequency. Besides, FIG. 5 also includes three graphs corresponding to three different impedance ratios K, in FIG. 5, each value of K has a value of α, and each value of α corresponds to a abscissa (fs1/f0) and a ordinate (fs2/f0). In the present embodiment, the first asymmetric stepped-impedance resonator 130, the second asymmetric stepped-impedance resonator 140, the third asymmetric stepped-impedance resonator 150 and the fourth asymmetric stepped-impedance resonator 160 are all corresponding to the relation diagram in the FIG. 5.

In the present embodiment, the value of K corresponding to the first asymmetric stepped-impedance resonator 130 and the second asymmetric stepped-impedance resonator 140 is 0.45, the value of a corresponding to the first asymmetric stepped-impedance resonator 130 and the second asymmetric stepped-impedance resonator 140 is 0.2, the value of K corresponding to the third asymmetric stepped-impedance resonator 150 and the fourth asymmetric stepped-impedance resonator 160 is 0.55, the value of a corresponding to the third asymmetric stepped-impedance resonator 150 and the fourth asymmetric stepped-impedance resonator 160 is 0.65. Of course, in other embodiment, the value of K and the value of a can be set as other values.

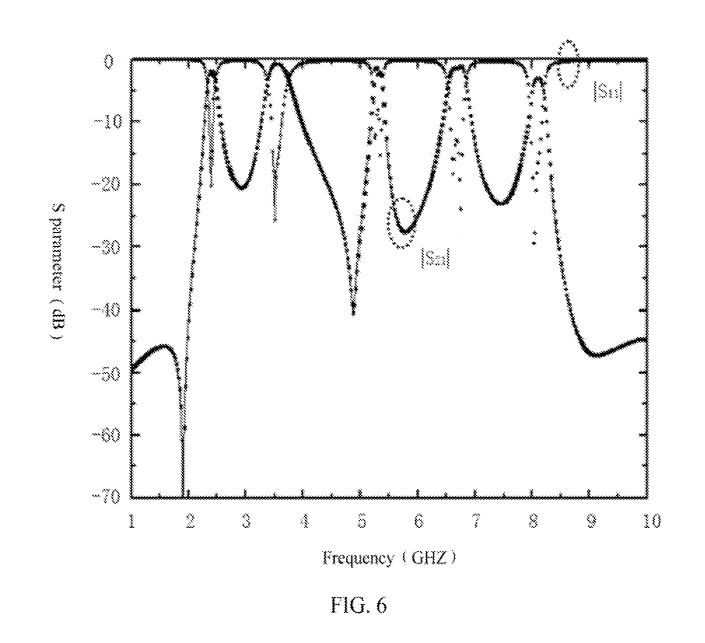

FIG. 6 is a frequency diagram of the bandpass filter 100 of FIGS. 1 and 2. Horizontal axis shows frequencies of signals which pass through the bandpass filter 100 (unit: GHZ), vertical axis shows amplitude (unit: dB), a quadrant includes a amplitude of a reflected scattering parameter (S-parameter: S11) and a amplitude of a transmitted scattering parameter (S-parameter: S21).

As shown in FIG. 6, the bandpass filter 100 can achieve 5 bandwidths. In FIG. 6, the central frequency of the first bandwidth is about 2.4 GHZ, and the amplitude of S21 corresponding to the first bandwidth is about −2.4 dB, the amplitude of S11 corresponding to the first bandwidth is about −20 dB; the central frequency of the second bandwidth is about 3.5 GHZ, and the amplitude of S21 corresponding to the second bandwidth is about −1.2 dB, the amplitude S11 corresponding to the second bandwidth is about −25 dB; the central frequency of the third bandwidth is about 5.2 GHZ, and the amplitude of S21 corresponding to the third bandwidth is about −2.0 dB, the amplitude of S11 corresponding to the third bandwidth is about −28 dB; the central frequency of the fourth bandwidth is about 6.8 GHZ, and amplitude of the S21 corresponding to the fourth bandwidth is about −2.0 dB, the amplitude of S11 corresponding to the fourth bandwidth is about −24 dB; the central frequency of the fifth bandwidth is about 8.0 GHZ, and the amplitude of S21 corresponding to the fifth bandwidth is about −4 dB, the amplitude of S11 corresponding to the fifth bandwidth is about −32 dB.

The above five bandwidths can be applied in to Wireless LAN (WLAN), Worldwide Interoperability for Microwave Access(WIMAX), Long Term Evolution (LTE), C wave band and X wave band. Besides, there are two transmission zeros corresponding to 1.8 GHZ and 4.8 GHZ, and as a result of two transmission zeros, selectivity of the bandpass filter 100 can improve to much.

The above-described embodiments are illustrative of the principles set forth herein, and do not limit the scope of the present disclosure. The described embodiments should not be construed as limited the following claims.

What is claimed is:

1. A bandpass filter comprising:
a first impedance resonator, comprising a first microstrip line and a second microstrip line, wherein the first microstrip line is perpendicular to the second microstrip line and forms a “T” shape with the second microstrip line;
a second impedance resonator which is axisymmetric to the first impedance resonator;
a first asymmetric stepped-impedance resonator located on one side of the first microstrip line, comprising a third microstrip line and a fourth microstrip line;
a second asymmetric stepped-impedance resonator which is axisymmetric to the first asymmetric stepped-impedance resonator and is located on one side of the first microstrip line;
a third asymmetric stepped-impedance resonator located on the other side of the first microstrip line, comprising a fifth microstrip line and a sixth microstrip line;
a fourth asymmetric stepped-impedance resonator which is axisymmetric to the third asymmetric stepped-impedance resonator and is located on the other side of the first microstrip line;
an input portion, comprising a seventh microstrip line and connecting with the first microstrip line; and
an output portion which is axisymmetric to the input portion and connects with the second impedance resonator.

2. The bandpass filter of claim 1, wherein the third microstrip line connects with the fourth microstrip line to collectively form a first rectangle with a first gap.

3. The bandpass filter of claim 2, wherein one side of the first rectangle defining the first gap is perpendicular to but does not meet the first microstrip line, and is close to the second microstrip line.

4. The bandpass filter of claim 3, wherein the fourth microstrip line is located on the side defining the first gap and is wider than the third microstrip line.

5. The bandpass filter of claim 1, wherein the fifth microstrip line connects with the sixth microstrip line to collectively form a second rectangle with a second gap, and one side defining the second gap is perpendicular to but does not meet the first microstrip line.

6. The bandpass filter of claim 1, wherein the sixth microstrip line is wider than the fifth microstrip line.

7. The bandpass filter of claim 1, wherein the input portion, the second microstrip line and the first asymmetric stepped-impedance resonator are placed on one side of the first microstrip line in turns.

8. A bandpass filter having two groups of resonators which are axisymmetric to each other, each group of resonators comprising:
a first resonator, comprising a seventh microstrip line presenting an “L” shape and a eighth microstrip line which is elongated, wherein the seventh microstrip line comprising a long part and a short part, wherein the long part is perpendicularly connected to the short part , and wherein the eight microstrip line is perpendicularly connected to the long part of the seventh microstrip line;
a second resonator presenting a third rectangle defining a third gap and being located on one side of the eighth microstrip line and one side of the long part of the seventh microstrip line, and wherein the short part of the seventh microstrip line is located on the other side of the eighth microstrip line;
a third resonator presenting a fourth rectangle defining a fourth gap and being located on the other side of the long part of the seventh microstrip line;
an input portion which is a joint of the long part and the short part in the seventh microstrip line; and
an output axisymmetric to the input portion.

9. The bandpass filter of claim 8, wherein the short part of the seventh microstrip line is wider than the long part of the seventh microstrip line.

10. The bandpass filter of claim 9, wherein a part of the second resonator near the third gap and the eighth microstrip line is wider than other parts of the second resonator.
